(19) United States
(12) Patent Application Publication
(10) Pub. No.: US 2007/0007945 A1
(43) Pub. Date: Jan. 11, 2007

(54) Automatic non-linear phase response calibration and compensation for a power measurement device

(75) Inventors: Craig L. King, Tuscon, AZ (US); Vincent Quiquempoix, Divonne les Bains (FR); Roger Berry, Walsden (GB)

Correspondence Address: BAKER BOTTS, LLP, 910 LOUISIANA, HOUSTON, TX, 77002-4995, US

(73) Assignee: Microchip Technology Incorporated

(21) Appl. No.: 11/502,222

(22) Filed: Aug. 10, 2006

Related U.S. Application Data
(62) Division of application No. 11/300,816, filed on Dec. 15, 2005.
(60) Provisional application No. 60/697,585, filed on Jul. 8, 2005.

(51) Int. Cl. G01R 11/32; G01R 7/00; G01R 25/00

(52) U.S. Cl. 324/142; 324/76.77

(57) ABSTRACT

Phase delay compensation sweep may be used in determining correct phase delay compensation of measured currents for substantially matching a measured apparent power to an expected apparent power over an operating range of current values of a current transformer (CT). A frequency sweep may also be used in determining correct phase delay compensation of each measured current in applications having multiple frequencies. Phase delay compensation for each CT current value may be stored in a phase delay compensation look-up table during the phase delay compensation sweep calibration and recalled from the look-up table during operational power measurements. Phase delay compensation for each CT current value and each frequency of that current value may be stored in a phase delay compensation look-up table during the phase delay compensation sweep calibration and recalled from the look-up table during operational power measurements.

### RELATED PATENT APPLICATIONS

This application claims priority to commonly owned U.S. Provisional Patent Application Ser. No. 60/697,585; filed Jul. 8, 2005; entitled “Automatic Non-Linear Phase Response Calibration and Compensation for an Energy Measurement Device,” by Craig L. King, Vincent Quiquempoix and Roger Berry; and is related to commonly owned U.S. patent application Ser. No. 11/028,381; filed Jan. 3, 2005; entitled “Direct Current Offset Cancellation And Phase Equalization For Power Metering Devices,” by Vincent Quiquempoix, both of which are hereby incorporated by reference herein for all purposes.

### TECHNICAL FIELD

The present disclosure, according to one embodiment, relates to power measurement devices, e.g., electronic power metering, and more particularly, to automatic non-linear phase response calibration and compensation in a power measurement device.

### BACKGROUND

In power metering or measurement systems, measured analog current and voltage channels are often digitized for ease in performing digital signal processing on the voltage and current information so as to produce a more accurate power measurement than may be obtained from a completely analog power metering system. Current Transformers (CTs) are the most popular device used for sensing current in power measurement, energy metering, power factor correction, and many other applications. However when evaluating the physical properties of a CT, each CT has its own non-linear phase response with respect to the I_{RMS} current flowing through the CT. This non-linear phase response may materially affect any power calculation that may use this CT as a current sensor for power measurements.

CT manufacturers supply typical characteristic curves showing the CT non-linear phase response, but each individual CT may vary from these typical characteristic curves and therefore may have to be compensated and calibrated individually for many applications requiring precise measurement results. The present industry approach to this problem is to use a phase compensation block in the current channel that may add or subtract phase delay (on the order of 1 microsecond) dependent upon the I_{RMS} being measured. The compensation delay for specific I_{RMS} values may be determined from a lookup table that may be generated when the system is being produced.

### SUMMARY

High accuracy power measurements using a non-linear current transformer require phase delay compensation of measured current values from the current transformer (CT) over the operating range thereof, e.g., current and/or frequency. A phase delay compensation sweep may be used in determining correct phase delay compensation of measured currents for substantially matching a measured apparent power to an expected apparent power over an operating range of current values. A frequency sweep may also be used in determining correct phase delay compensation for each measured current range in applications having multiple frequencies, e.g., variable frequency motor drive, audio power amplifier, radio frequency amplifier, sonar generator, seismic power source, etc.

According to a specific example embodiment of the present disclosure, a power measurement device having phase delay calibration and compensation may comprise a first analog-to-digital converter (ADC) having an analog input adapted for coupling to a voltage, and a digital output representative of the voltage; a second ADC having an analog input adapted for coupling to a current, and a digital output representative of the current; a first digital high pass filter (HPF) having an input coupled to the first ADC output; adjustable phase delay coupled to the second ADC output; a second digital HPF having an input coupled to the adjustable phase delay compensation; a digital multiplier having a first input coupled to an output of the first digital HPF, a second input coupled to an output of the second digital HPF, and an output having a product of the voltage and current; a digital low pass filter (LPF) having an input coupled to the output of the digital multiplier, and an output having a power value; a digital processor coupled to the digital LPF; a phase delay compensation look-up table coupled to and controlled by the digital processor, wherein the phase delay compensation look-up table supplies a phase delay compensation value based upon a respective current value used by the adjustable phase delay; and a calibration circuit for determining the phase delay compensation value for each of the respective current values.

According to another specific example embodiment of the present disclosure, a power measurement system having phase delay calibration and compensation may comprise a potential transformer coupled to a power source for measuring a voltage thereof; a first analog-to-digital converter (ADC) having an analog input coupled to the potential transformer and a digital output representative of the voltage; a current transformer coupled to the power source for measuring a current thereof; a second ADC having an analog input coupled to the current transformer and a digital output representative of the current; a first digital high pass filter (HPF) having an input coupled to the first ADC output; adjustable phase delay coupled to the second ADC output; a second digital HPF having an input coupled to the adjustable phase delay compensation; a digital multiplier having a first input coupled to an output of the first digital HPF, a second input coupled to an output of the second digital HPF, and an output having a product of the voltage and current; a digital low pass filter (LPF) having an input coupled to the output of the digital multiplier, and an output having a power value; a digital processor coupled to the digital LPF; a phase delay compensation look-up table coupled to and controlled by the digital processor, wherein the phase delay compensation look-up table supplies a phase delay compensation value based upon a respective current value used by the adjustable phase delay; a calibration circuit for determining the phase delay compensation value for each of the respective current values; and an adjustable load coupled to the power source.

According to still another specific example embodiment of the present disclosure, a method for automatic non-linear phase response calibration and compensation for a power measurement device may comprise the steps of: a) entering an expected apparent power value (PAE) and a calibration point N; b) storing the PAE and the calibration point N; c) starting a sweep calibration for determining phase delay compensation, wherein the sweep calibration may comprise: 1) determining voltage and current values; 2) calculating an apparent power (PA) from the voltage and current values; 3) comparing the PAE and the PA, wherein: i) if the PA is less than the PAE, then decreasing a phase delay of the current value and returning to step 2), ii) if the PAE is less than the PA, then increasing the phase delay of the current value and returning to step 2), and iii) if the PA is substantially equal to the PAE, then saving the current value and the phase delay to address N of a look-up table. The method may further comprise the steps of: d) calculating a new current value; e) comparing the new current value with a previous current value, wherein: 1) if the difference between the new current value and the previous current value is less than or equal to a current increment value, then returning to step d), and 2) if the difference between the new current value and the previous current value is greater than the current increment value, then retrieving the phase delay from the address N associated with the new current value, and using the phase delay retrieved from the address N in step d) for calculating the new current value.

According to still another specific example embodiment of the present disclosure, a method for automatic non-linear phase response calibration and compensation for a power measurement device may comprise the steps of: a) entering an expected apparent power value (PAE) and a calibration point N; b) storing the PAE and the calibration point N; c) starting a sweep calibration for determining phase delay compensation, wherein the sweep calibration may comprise: 1) determining voltage and current values; 2) calculating an apparent power (PA) from the voltage and current values; 3) comparing the PAE and the PA, wherein: i) if the PA is less than the PAE, then decreasing a phase delay of the current value and returning to step 2), ii) if the PAE is less than the PA, then increasing the phase delay of the current value and returning to step 2), and iii) if the PA is substantially equal to the PAE, then saving the current value and the phase delay to address N of a look-up table.

According to yet another specific example embodiment of the present disclosure, a method for automatic non-linear phase response calibration and compensation for a power measurement device may comprise the steps of: a) entering an expected apparent power value (PAE) and calibration points M and N; b) storing the PAE and the calibration points M and N; c) starting a sweep calibration for determining phase delay compensation, wherein the sweep calibration comprises: 1) determining voltage and current values, and frequency; 2) calculating an apparent power (PA) from the voltage and current values; 3) comparing the PAE and the PA, wherein: i) if the PA is less than the PAE, then decreasing a phase delay of the current value and returning to step 2), ii) if the PAE is less than the PA, then increasing the phase delay of the current value and returning to step 2), and iii) if the PA is substantially equal to the PAE, then saving the current value and the phase delay to address N of a look-up table, and the frequency to address M of the look-up table. The method may further comprise the steps of: d) calculating a new current value; e) comparing the new current value with a previous current value, wherein: 1) if the difference between the new current value and the previous current value is less than or equal to a current increment value, then returning to step d), and 2) if the difference between the new current value and the previous current value is greater than the current increment value, then retrieving the phase delay from the addresses M and N associated with the frequency and new current value, respectively, and using the phase delay retrieved from the addresses M and N for step d) in calculating the new current value.

### BRIEF DESCRIPTION OF THE DRAWINGS

A more complete understanding of the present disclosure thereof may be acquired by referring to the following description taken in conjunction with the accompanying drawing, wherein:

FIG. 1 illustrates a schematic functional block diagram of a power measurement device, according to a specific example embodiment of the present disclosure;

FIG. 2 illustrates a diagram of a flow chart that may functionally describe operation of a power measurement device when calibrating for a current transformer (CT) at a plurality of different current values, according to a specific example embodiment of the present disclosure;

FIG. 3 illustrates a diagram of a flow chart that may functionally describe operation of a power measurement device when compensating for a current transformer (CT) at a plurality of different current values, according to a specific example embodiment of the present disclosure;

FIG. 4 illustrates a diagram of a flow chart that may functionally describe operation of a power measurement device when calibrating for a current transformer (CT) at a plurality of different current and frequency values, according to another specific example embodiment of the present disclosure;

FIG. 5 illustrates a diagram of a flow chart that may functionally describe operation of a power measurement device when compensating for a current transformer (CT) at a plurality of different current and frequency values, according to another specific example embodiment of the present disclosure.

While the present disclosure is susceptible to various modifications and alternative forms, specific example embodiments thereof have been shown in the drawings and are herein described in detail. It should be understood, however, that the description herein of specific example embodiments is not intended to limit the disclosure to the particular forms disclosed herein, but on the contrary, this disclosure is to cover all modifications and equivalents as defined by the appended claims.

### DETAILED DESCRIPTION

Referring now to the drawings, the details of example embodiments are schematically illustrated. Like elements in the drawings will be represented by like numbers, and similar elements will be represented by like numbers with a different lower case letter suffix.

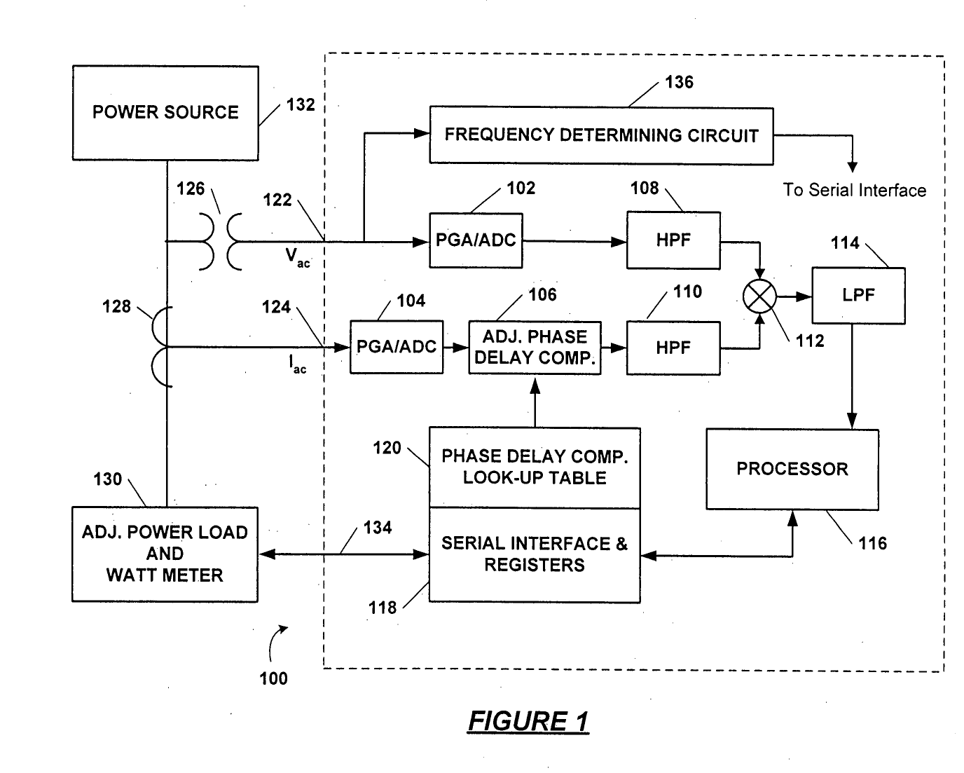

Referring to FIG. 1, depicted is a schematic functional block diagram of a power measurement device, according to a specific example embodiment of the present disclosure. The power measurement device, generally represented by the numeral 100, may comprise a first analog-to-digital convert (ADC) 102, a second ADC 104, a first digital high pass filter (HPF) 108, an adjustable phase delay compensation block 106, a second digital HPF 110, a multiplier 112, a digital low pass filter (LPF) 114, a digital processor 116, an interface and registers 118, and a phase delay compensation look-up table 120.

The first ADC 102 and the second ADC 104 may also include a programmable gain amplifier. The first ADC 102 may be coupled to a potential transformer (PT) 126 that may be coupled to a power source 132. The PT 126 and first ADC 102 may be used for measuring the voltage of the power source 132. An adjustable power load and wattmeter 130 may be coupled to the power source 132, and the current drawn by the adjustable load 130 may be monitored by a current transformer (CT) 128. The second ADC 104 may be coupled to the CT 128 and may be used for measuring the current drawn by the adjustable load 132. A frequency determination circuit 136 may be used for determining the frequency of the power source 132. The power source 132 may be capable of generating a plurality of different frequencies for applications requiring a variable frequency power source, e.g., variable frequency motor drive, audio power amplifier, radio frequency amplifier, sonar generator, seismic energy source, etc.

The power measurement device 100 may perform both automatic calibration and compensation for a non-linear phase response of the current transformer 128 coupled thereto. In a calibration mode, the power measurement device 100 may ‘sweep’ the adjustable phase delay compensation block 106 until a phase delay compensation value results in the calculation of power values that match the expected power values, and then save the phase delay compensation value and corresponding I_{RMS} value in the phase delay compensation look-up table 120. In a compensation mode, the power measurement device 100 may detect a change in the I_{RMS} value, look up the corresponding phase delay compensation value in the look-up table 120 and then program this phase delay compensation value in the phase delay compensation block 106 of the current measurement channel (e.g., ADC 104, phase delay compensation block 106 and HPF 110).

The interface and registers 118 may be coupled to the digital processor 116. The interface and registers 118 may also be coupled to the adjustable load 130 via a bus 134, e.g., serial bus. The processor 116 may control the current drawn by the adjust load 130 during a calibration mode as described more fully herein. A wattmeter may be coupled to or be part of the adjustable load 130 for determining actual power during the calibration mode. The actual power values may be used during calibration of the power measurement device 100. The interface and registers 118 may also couple the processor 116 to the phase delay compensation look-up table 120.

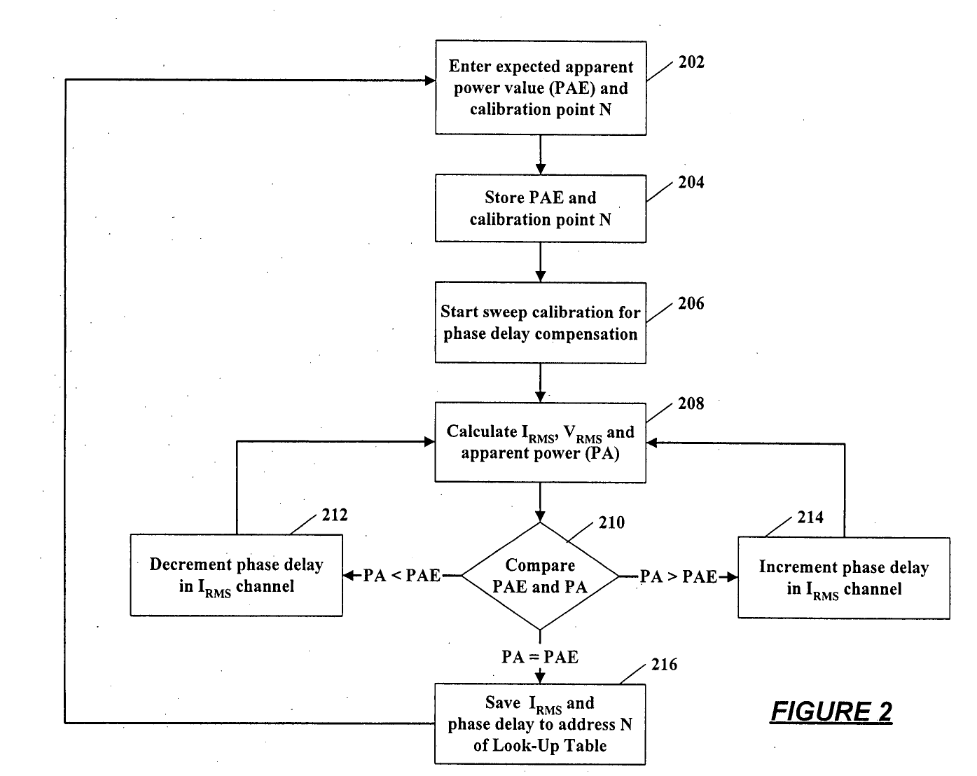

Referring to FIG. 2, depicted is a diagram of a flow chart that may functionally describe operation of a power measurement device when calibrating for a current transformer (CT) at a plurality of different current values, according to a specific example embodiment of the present disclosure. In step 202, an expected apparent power value (PAE) and calibration point N may be entered. The calibration point may be a current value in a range defined by N ranges. Wherein the number of current value ranges between the minimum and maximum current values at which the CT 128 will operate may be divided into N current ranges, wherein N may be the bit resolution of the ADC 104 or whatever resolution is desired based upon available memory storage capacity of the look-up table 120. In step 204, the PAE and calibration point N may be stored. Then in step 206, a sweep calibration begins for determining required phase delay compensation for the current range specified.

Referring back to FIG. 1, the measured V_{AC} value and I_{AC} value at inputs 122 and 124, respectively, are converted from analog values to digital values by the ADCs 102 and 104, respectively. The digital current value has its phase delay compensated by the adjustable phase delay compensation block 106. An arbitrary phase delay compensation value may be used initially, however, an iterative process may be used in determining the phase delay compensation required for substantially correct calibrating of the CT 128. Other processes for determining the required phase delay compensation may also be used and are contemplated herein. The digital V_{AC} value and phase delay compensated digital I_{AC} value are multiplied in the digital multiplier 112 and the product, apparent power (PA), is presented to an input of the processor 116.

Referring back to FIG. 2, in step 208, V_{RMS} and I_{RMS} may be calculated from the aforementioned digital V_{AC} value and phase delay compensated digital I_{AC} value, respectively, and the apparent power (PA) may be calculated from I_{RMS} and V_{RMS}. In step 210, the PAE and PA are compared. If PA is substantially equal to PAE, then the I_{RMS} value and associated phase delay may be saved in step 216 at an appropriate address N of the look-up table 120. If PAE is sufficiently greater than PA, then the phase delay in the I_{RMS} channel is decreased (decremented) in step 212 and the I_{RMS} and PA may be recalculated in step 208 using the new phase delay determined in step 212. Or if PA is sufficiently greater than PAE, then the phase delay in the I_{RMS} channel is increased (incremented) in step 214 and the I_{RMS} and PA may be recalculated in step 208 using the new phase delay determined in step 214. Determination for the appropriate phase delay compensation for each range of I_{RMS}, e.g., N ranges, may be stored in the look-up table 120 or any other memory. The memory may be non-volatile, e.g., electrically erasable and programmable read only memory (EEPROM), Flash, etc., or the memory may be dynamic random access memory (DRAM), static random access memory (SRAM) etc., with or without battery back-up.

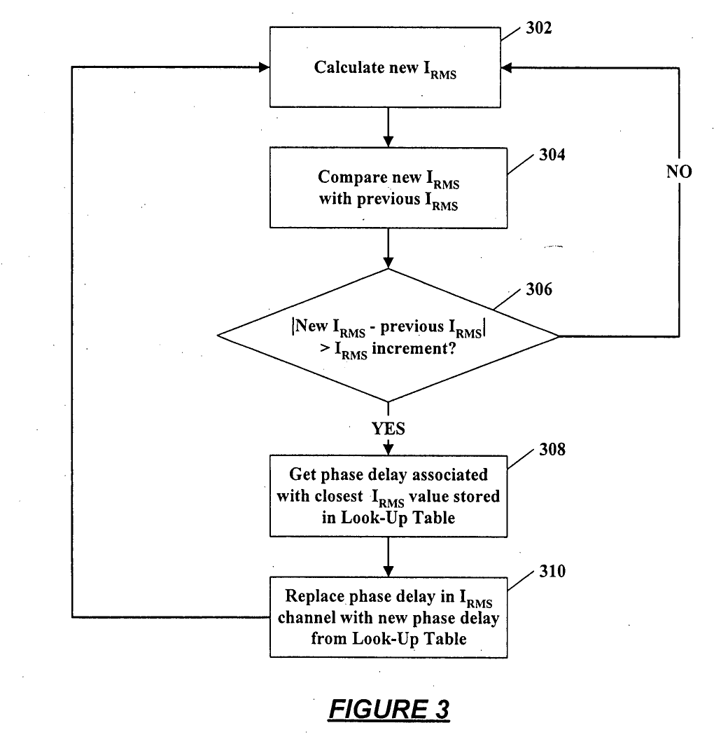

Referring to FIG. 3, depicted is a diagram of a flow chart that may functionally describe operation of a power measurement device when compensating for a current transformer (CT) at a plurality of different current values, according to a specific example embodiment of the present disclosure. In step 302 a new I_{RMS} value is calculated. In step 304 the new I_{RMS} value is compared to the previous I_{RMS} value. In step 306 the difference between the new and previous I_{RMS} values is compared to determine if the difference is greater than an I_{RMS} increment value. If not, new I_{RMS} values continue to be calculated. If the difference is greater than the I_{RMS} increment value then in step 308 a new phase delay compensation value, corresponding to the one closest to the I_{RMS} value, is retrieved from the phase delay compensation look-up table 120. In step 310, the retrieved phase delay compensation value may be used in calculating the new I_{RMS} value in step 302.

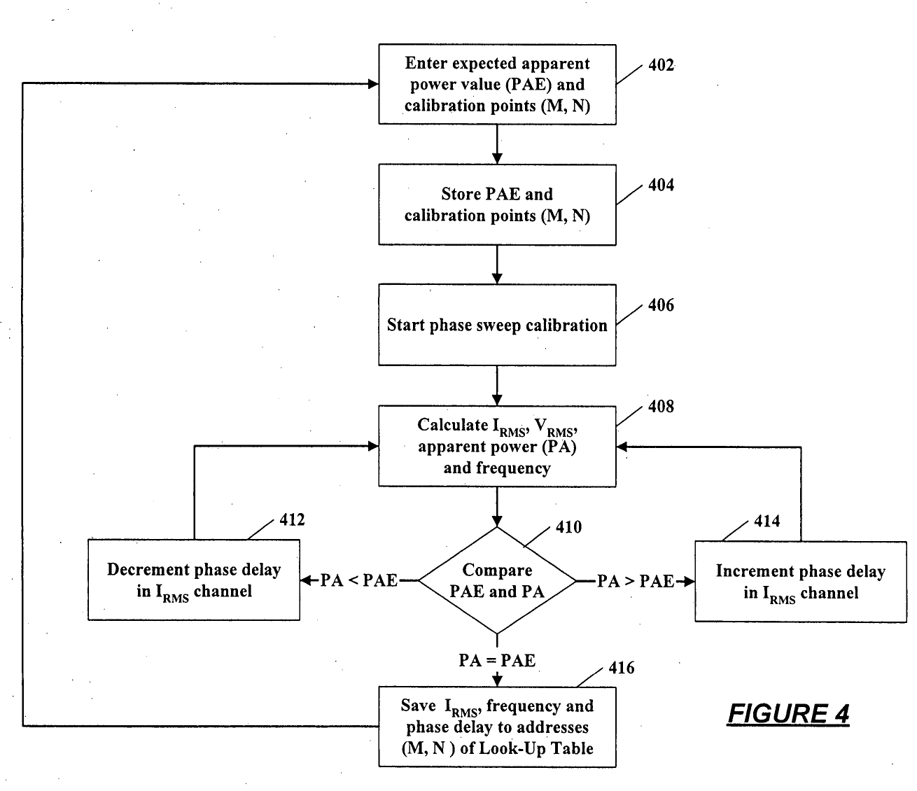

Referring to FIG. 4, depicted is a diagram of a flow chart that may functionally describe operation of a power measurement device when calibrating for a current transformer (CT) at a plurality of different current and frequency values, according to another specific example embodiment of the present disclosure. In step 402, an expected apparent power value (PAE) and calibration points M and N may be entered. The calibration points M and N may be a frequency value and a current value in ranges defined by M and N, respectively. Wherein the number of frequency ranges between the minimum and maximum frequencies at which the CT 128 will operate may be divided into M ranges, and the number of current value ranges between the minimum and maximum current values at which the CT 128 will operate may be divided into N ranges, wherein M and N may each have bit resolutions of the ADC 104 or whatever resolutions are desired based upon available memory storage capacity of the look-up table 120. In step 404, the PAE and calibration references M and N may be stored. Then in step 406, a sweep calibration begins for determining required phase delay compensation for the frequency and current ranges specified.

In step 408, I_{RMS} and V_{RMS} are calculated from the aforementioned digital V_{AC} value and phase delay compensated digital I_{AC} value, respectively, and the apparent power (PA) may be calculated from I_{RMS} and V_{RMS}. In step 410, the PAE and PA are compared. If PA is substantially equal to PAE, then the I_{RMS} value, associated frequency and phase delay may be saved in step 416 at appropriate addresses M and N, respectively, of the look-up table 120. If PAE is sufficiently greater than PA, then the phase delay in the I_{RMS} channel is decreased (decremented) in step 412 and the I_{RMS} and PA may be recalculated in step 408 using the new phase delay determined in step 412. Or if PA is sufficiently greater than PAE, then the phase delay in the I_{RMS} channel is increased (incremented) in step 414 and the I_{RMS} and PA may be recalculated in step 408 using the new phase delay determined in step 414. Determination for the appropriate phase delay compensation for each range of frequencies and I_{RMS}, e.g., M and N ranges, respectively, may be stored in the look-up table 120 or any other memory. The memory may be non-volatile, e.g., electrically erasable and programmable read only memory (EEPROM), Flash, etc., or the memory may be dynamic random access memory (DRAM), static random access memory (SRAM) etc., with or without battery back-up.

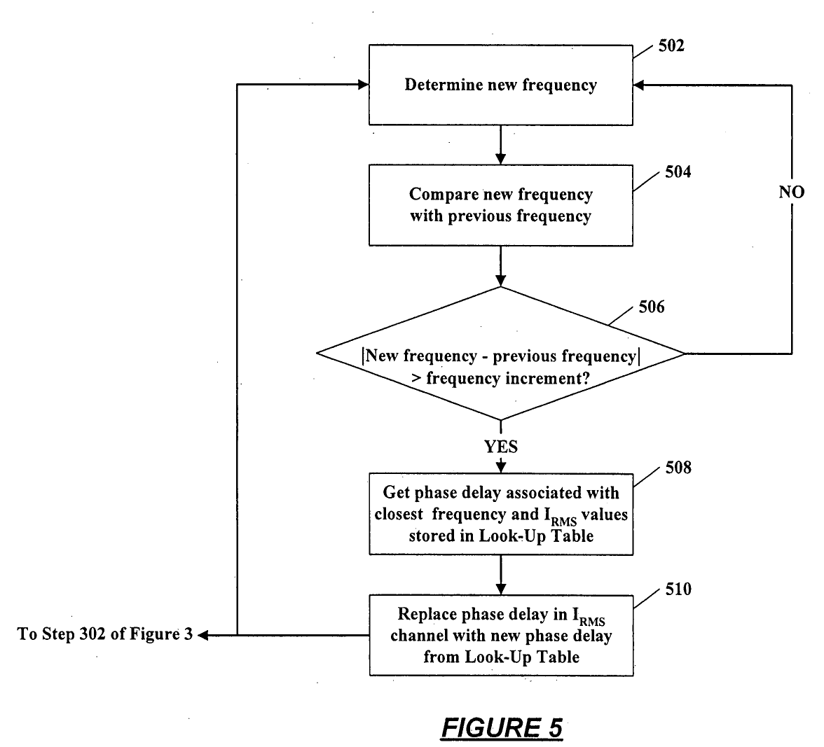

Referring to FIG. 5, depicted is a diagram of a flow chart that may functionally describe operation of a power measurement device when compensating for a current transformer (CT) at a plurality of different current and frequency values, according to another specific example embodiment of the present disclosure. In step 502 a new frequency is determined. In step 504 the new frequency is compared to the previous frequency. In step 506 the difference between the new and previous frequencies is compared to determine if the difference is greater than a frequency increment value. If not, new frequencies continue to be determined. If the difference is greater than the frequency increment value, then in step 508 a new phase delay compensation value, corresponding to the one closest to the frequency and calculated I_{RMS} (see FIG. 3) values, is retrieved from the phase delay compensation look-up table 120. In step 510, the retrieved phase delay compensation value may be used in calculating the new I_{RMS} value in step 302 (see FIG. 3).

While embodiments of this disclosure have been depicted, described, and are defined by reference to example embodiments of the disclosure, such references do not imply a limitation on the disclosure, and no such limitation is to be inferred. The subject matter disclosed is capable of considerable modification, alteration, and equivalents in form and function, as will occur to those ordinarily skilled in the pertinent art and having the benefit of this disclosure. The depicted and described embodiments of this disclosure are examples only, and are not exhaustive of the scope of the disclosure.

1-12. (canceled)

13. A method for automatic non-linear phase response calibration and compensation for a power measurement device, said method comprising the steps of:
a) entering an expected apparent power value (PAE) and a calibration point N;
b) storing the PAE and the calibration point N;
c) starting a sweep calibration for determining phase delay compensation, wherein the sweep calibration comprises:
1) determining voltage and current values;
2) calculating an apparent power (PA) from the voltage and current values;
3) comparing the PAE and the PA, wherein:
i) if the PA is less than the PAE, then decreasing a phase delay of the current value and returning to step 2),
ii) if the PAE is less than the PA, then increasing the phase delay of the current value and returning to step 2), and
iii) if the PA is substantially equal to the PAE, then saving the current value and the phase delay to address N of a look-up table.

14. The method according to claim 13, further comprising the steps of:
d) calculating a new current value;
e) comparing the new current value with a previous current value, wherein:
1) if the difference between the new current value and the previous current value is less than or equal to a current increment value, then returning to step d), and
2) if the difference between the new current value and the previous current value is greater than the current increment value, then retrieving the phase delay from the address N associated with the new current value, and using the phase delay retrieved from the address N in step d) for calculating the new current value.

15. A method for automatic non-linear phase response calibration and compensation for a power measurement device, said method comprising the steps of:
a) entering an expected apparent power value (PAE) and calibration points M and N;
b) storing the PAE and the calibration points M and N;
c) starting a sweep calibration for determining phase delay compensation, wherein the sweep calibration comprises:
1) determining voltage and current values, and frequency;
2) calculating an apparent power (PA) from the voltage and current values;
3) comparing the PAE and the PA, wherein:
i) if the PA is less than the PAE, then decreasing a phase delay of the current value and returning to step 2),
ii) if the PAE is less than the PA, then increasing the phase delay of the current value and returning to step 2), and
iii) if the PA is substantially equal to the PAE, then saving the current value and the phase delay to address N of a look-up table, and the frequency to address M of the look-up table.

16. The method according to claim 15, further comprising the steps of:
d) calculating a new current value;
e) comparing the new current value with a previous current value, wherein:
1) if the difference between the new current value and the previous current value is less than or equal to a current increment value, then returning to step d), and
2) if the difference between the new current value and the previous current value is greater than the current increment value, then retrieving the phase delay from the addresses M and N associated with the frequency and new current value, respectively, and using the phase delay retrieved from the addresses M and N for step d) in calculating the new current value.
